(19) United States
(12) Patent Application Publication
(10) Pub. No.: US 2008/0187685 A1
(43) Pub. Date: Aug. 7, 2008

(54) Method of preparing vertically-aligned carbon nanotube under atmospheric and cold-wall heating treatments and making the same

(75) Inventors: Tsun-Neng Yang, Taipei City (TW); Shan-Ming Lan, Daxi Town (TW)

Correspondence Address: TROXELL LAW OFFICE PLLC, 5205 LEESBURG PIKE, SUITE 1404, FALLS CHURCH, VA, 22041, US

(73) Assignee: ATOMIC ENERGY COUNCIL - INSTITUTE OF NUCLEAR ENERGY RESEARCH, Taoyuan (TW)

(21) Appl. No.: 11/703,205

(22) Filed: Feb. 7, 2007

(51) Int. Cl. C23C 14/14; H05B 7/00

(52) U.S. Cl. 427/597; 427/596

(57) ABSTRACT

A carbon nanotube is prepared under a non-vacuum environment. An atmospheric pressure chemical vapor deposition (APCVD) is processed with an external high frequency source and a perpendicularly-supplied gas material source for a cold-wall heating treatment. The carbon nanotube is thus obtained with a vertically aligned arrangement at a high speed and a pure quality for production.

### FIELD OF THE INVENTION

The present invention relates to preparing carbon nanotubes; more particularly, relates to using an external high frequency source and a perpendicularly-supplied gas material source for a cold-wall heating treatment under a non-vacuum environment to directly grow carbon nanotubes having a vertically-aligned arrangement on a surface of a catalyst material.

### DESCRIPTION OF THE RELATED ART

As early as 1991, Mr. Sumio Lijima in NEC Co., Japan found a carbon nanotube formed in an arc discharging device. Because the carbon nanotube has good electronical and mechanical characteristics, it can be applied to electronical devices, computing devices and field emitting devices; or sensors, electrodes, high-strength composite materials, etc.

In the early days, carbon nanotubes are fabricated through laser ablation or arc discharging. On being fabricated through the laser ablation, it is hard to be productive. Through arc discharging, carbon nanotubes are productive yet with less purity.

In recent years, carbon nanotubes are fabricated mainly through plasma-enhanced chemical vapor deposition (PECVD) and hot-wall heating treatment. However, PECVD has to be operated under a vacuum environment; and the hot-wall heating treatment has a slow temperature change resulting in a longer time spent.

Hence, the prior arts do not fulfill users' requests on actual use.

### SUMMARY OF THE INVENTION

The main purpose of the present invention is to use a perpendicularly-supplied gas material source and an external high frequency source for a cold-wall heating treatment under a non-vacuum environment to directly grow carbon nanotubes having a vertically-aligned arrangement on a surface of a catalyst material.

To achieve the above purpose, the present invention is a method of preparing vertically-aligned carbon nanotubes under atmospheric and cold-wall heating treatments and making the same, comprising steps of: (a) obtaining a silicon (Si) substrate; (b) by using an electron-beam gun (E-gun) evaporation system, coating a buffer layer and a catalyst layer; (c) deposing the Si substrate into a reaction furnace for atmospheric pressure chemical vapor deposition (APCVD) to grow carbon nanotubes with an external high frequency source and a perpendicularly-supplied gas material source for a cold-wall heating treatment; and (d) cooling down temperature to room temperature to finish growing carbon nanotubes, where the reaction furnace is operated under 1 atmosphere between 800 and 850 Celsius degrees (° C.); after a pre-treatment for 1 to 10 minutes (min), temperature is lowered to a temperature between 700 and 800° C.; the carbon nanotubes are grown for 0.1 to 10 min with a speed of several micrometers per minute (μm/min and a vertically aligned arrangement; and the temperature is fast ascended and descended to save time and power consumption. Accordingly, a novel method of preparing vertically-aligned carbon nanotubes under atmospheric and cold-wall heating treatments and making the same is obtained.

### BRIEF DESCRIPTIONS OF THE DRAWINGS

The present invention will be better understood from the following detailed description of the preferred embodiment according to the present invention, taken in con junction with the accompanying drawings, in which

FIG. 1 is the flow view showing the preferred embodiment according to the present invention; and

FIG. 2 to FIG. 5 are the views showing the preparing of the carbon nanotubes.

### DESCRIPTION OF THE PREFERRED EMBODIMENT

The following description of the preferred embodiment is provided to understand the features and the structures of the present invention

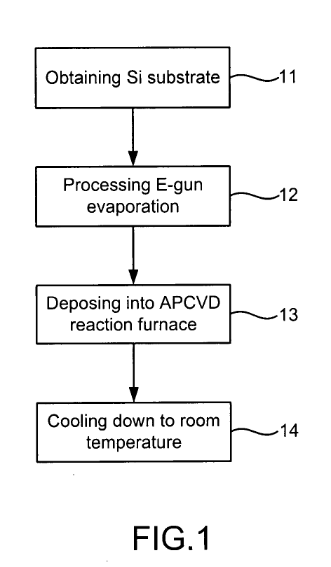

Please refer to FIG. 1 to FIG. 5, which are a flow view showing a preferred embodiment and views showing preparing of carbon nanotubes according to the present invention. As shown in the figures, the present invention is a method of preparing vertically-aligned carbon nanotubes under atmospheric and cold-wall heating treatments and making the same, comprising the following steps:

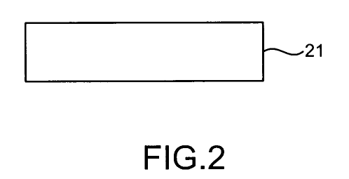

(a) Obtaining a Si substrate 11: As shown in FIG. 2, a silicon (Si) substrate 21 is obtained, where the Si substrate 21 is a p-type Si substrate or an n-type Si substrate.

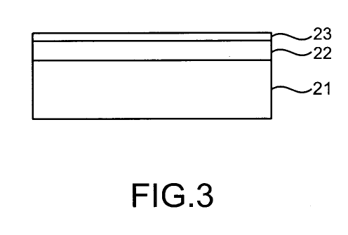

(b) Processing an E-gun evaporation 12: As shown in FIG. 3, an electron-beam gun (E-gun) evaporation system is used to coat a buffer layer 22 on the Si substrate 21 and then a catalyst layer 23 on an upper surface of the buffer layer 22, where the buffer layer is a metal film of titanium (Ti) and the catalyst layer is a metal film of nickel (Ni) or iron (Fe).

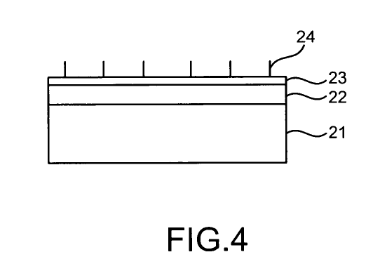

(c) Deposing into a reaction furnace of APCVD 13: As shown in FIG. 4, the Si substrate is put into an atmospheric pressure chemical vapor deposition (APCVD) system. The system is a reaction furnace using an external high frequency source and a perpendicularly-supplied gas material source for a cold-wall heating treatment with an ammonia gas (NH₃) under 1 atmosphere between 800 and 850 Celsius degrees (° C.) to process a pretreatment of surface erosion on a catalyst material for 0.1 to 10 minutes (min). Then temperature is lowered to a temperature between 700 and 800° C. with NH₃ supplied; and acetylene (C₂H₂) is transported to the reaction furnace through hydrogen (H₂) as a carbon source for growing carbon nanotubes 24. Therein the carbon nanotubes are grown for 0.1 to 10 min with a speed of several micrometers per minute (μm/min) and a vertically aligned arrangement.

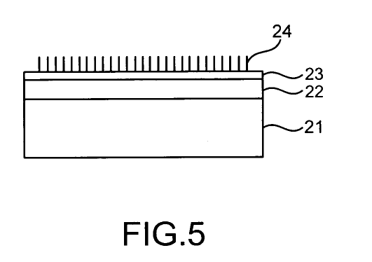

(d) Cooling down to room temperature 14: And, as shown in FIG. 5, gases of NH₃, H₂ and C₂H₂ are shut and the Si substrate 11 grown with carbon nanotubes 24 is cooled down to room temperature to be taken out to finish the whole procedure of growing carbon nanotubes 24.

To sum up, the present invention is a method of preparing vertically-aligned carbon nanotubes under atmospheric and cold-wall heating treatments and making the same, where an APCVD is used under a non-vacuum environment with an external high frequency source and a perpendicularly-supplied gas material source for a cold-wall heating treatment to directly grow carbon nanotubes on a surface of a catalyst material; the equipments used are simple; temperature is fast ascended and descended; less power is consumed; and carbon nanotubes are grown faster, purer and more productive.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of preparing vertically-aligned carbon nanotubes under atmospheric and cold-wall heating treatments and making the same comprising steps of:
(a) obtaining a silicon (Si) substrate;
(b) coating a buffer layer on said Si substrate and then a catalyst layer on said buffer layer by using an electron-beam gun (E-gun) evaporation system;
(c) deposing said Si substrate into a reaction furnace for atmospheric pressure chemical vapor deposition (APCVD) to process a pre-treatment through a cold-wall heating treatment under an ammonia gas (NH₃) with an external high frequency source and a perpendicularly-supplied gas material source, then transporting acetylene (C₂H₂) into said reaction furnace by hydrogen (H₂) as a carbon source on growing carbon nanotubes; and
(d) stopping supplying said N H₃, said H₂ and said C₂H₂ growing carbon nanotubes on said Si substrate, and taking out said Si substrate after lowering temperature to a room temperature.

2. The method according to claim 1,
wherein said Si substrate is selected from a group consisting of an n-type Si substrate and a p-type Si substrate.

3. The method according to claim 1,
wherein said buffer layer is a titanium (Ti) metal film.

4. The method according to claim 1,
wherein said catalyst layer is a film of a metal selected from a group consisting of nickel (Ni) and iron (Fe).

5. The method according to claim 1,
wherein said reaction furnace is operated at 1 atmosphere between 800 and 850 Celsius degrees (° C.) to heighten temperature for 5 to 60 minutes (min) and then is processed with said pre-treatment with said ammonia gas for 1 to 10 min.

6. The method according to claim 5,
wherein, after said p re-treatment, temperature is lowered to a temperature between 800 and 850° C. within a period between 5 and 60 min

7. The method according to claim 1,
wherein said carbon nanotubes are grown for 0.1 to 10 min.

8. The method according to claim 1,
wherein said carbon nanotubes grow 5 to 100 micrometers per minute (μm/min) and are vertically aligned.
